(19) United States
(12) Patent Application Publication
(10) Pub. No.: US 2006/0098373 A1
(43) Pub. Date: May 11, 2006

(54) Intelligent transient blocking unit

(75) Inventors: Francois Hebert, San Mateo, CA (US); Richard Harris, Palo Alto, CA (US)

Correspondence Address: GROOVER & HOLMES, BOX 802889, DALLAS, TX, 75380-2889, US

(73) Assignee: Fultec Semiconductors, Inc.

(21) Appl. No.: 11/130,793

(22) Filed: May 17, 2005

Related U.S. Application Data
(60) Provisional application No. 60/626,370, filed on Nov. 9, 2004.

(51) Int. Cl. H02H 9/06

(52) U.S. Cl. 361/118

(57) ABSTRACT

A TBU system that includes a TBU combined with control and monitoring features. For example, in one embodiment, TBU elements are combined with a status indication switch or indicator. In another embodiment, TBU elements are combined with event logging for over voltage conditions, over current conditions, including an indication of when the event occurred and an amount of energy that was let through.

### CROSS-REFERENCE TO OTHER APPLICATIONS

This application claims priority from U.S. provisional Application 60/626,370 filed Nov. 9, 2004, which is hereby incorporated by reference.

### BACKGROUND AND SUMMARY OF THE INVENTION

1. Field of the Invention

The present invention relates to surge protecting circuits, and more specifically to transient blocking units with intelligent monitoring capability.

2. Background

Surge protection is an important element to many electrical systems, particularly for telecom, data applications and other sensitive systems such as high frequency coaxial lines. Lightning and other power events can induce sudden short-lived or long-lived electrical surges or transients. Such events can damage or destroy sensitive electrical equipment. Effective systems which protect against such surges are available, but have serious drawbacks in terms of effectiveness, reliability, complexity and reduction in bandwidth.

One type of protection circuit is known as a polymer PTC or positive temperature coefficient, also known as a thermistor. In its normal state, the material in the PTC is in the form of a dense crystal, with many carbon particles packed together to form conductive pathways with low resistance. When the material is heated from excessive current, the polymer expands, pulling the carbon chains apart and greatly increasing the resistance. Such devices remain in the tripped or open state until the voltage is removed and the temperature decreases.

Another type of circuit protection is the transient blocking unit, or TBU. Like a PTC, the TBU works in series. TBUs typically have a much faster response time than PTCs. Typical TBUs do not require a power supply and do not limit circuit bandwidth. In addition, the electrical performance of TBUs does not drift or change after being exposed to transient events or electrical surges, unlike PTCs.

FIG. 1 shows a TBU, which can protect a load from voltage and/or current transient spikes or surges. In this example, the protection circuit is a unidirectional device, and is shown with an n-channel depletion mode device 102 and a p-channel depletion mode device 104. Depletion mode devices have a low on-resistance when the voltage difference between gate and source (V_{gs}) is equal to zero, and are turned off by applying a negative bias (for n-channel) or positive bias (for p-channel) on the gate (with respect to the device's source).

The n-channel device 102 is turned off by the voltage drop across the p-channel device 104. This voltage drop, shown as V_{gsp}, increases as the load increases. As the n-channel device 102 is turned off, its resistance increases, which in turn increases the voltage drop across its drain and source. The p-channel device 104 then turns off since its gate is connected to the input terminal from where the transient is coming. The device depicted in FIG. 1 is a unidirectional device, meaning this circuit is designed to handle an input surge from only one end. Bi-directional TBUs also exist which can protect against surges from two ends, as depicted below.

FIG. 2 shows a prior art bi-directional TBU. This example shows two n-channel depletion mode devices 202 and 206 with a p-channel depletion mode device 204. Also shown are two sets of diode, resistor, or combination 208, 210 placed between the gate of the p-channel device 204 and the loads at either end of this example bi-directional TBU. These devices 208, 210, when attached to the gate lead, reduce the need for a high gate breakdown voltage. The differences between p-channel and n-channel TBUs are discussed further below.

FIG. 3 shows an example TBU, but with p-channel devices connected to the input terminals instead of n-channel devices. This device functions similarly to that of FIG. 2 except for the obvious differences in carrier type of the depletion mode devices 302 (which is p-channel in this example), 304 (which is n-channel in this example) and 306 (which is p-channel in this example). Also shown are diodes, resistors, or combinations thereof 308, 310.

The example of FIG. 2, showing n-channel devices connected to the input terminals, is generally considered the most efficient for several reasons. For example, the device connected to the input is used to block high voltage transient once the TBU is turned off, which requires the input device to have a high breakdown voltage while having a low series resistance, low cost, and small size. N-channel devices have lower resistance than p-channel devices because of the differences between electron and hole mobility. N-channel devices are also preferred because low resistance, high breakdown voltage devices are more commonly available as n-channel than as p-channel.

A TBU is preferred to have a low series resistance and to have a low voltage drop across its elements. It should be of low cost and small size, and be compatible with high volume manufacturing processes, such as semiconductor fabrication. TBUs are preferably robust and have high reliability and repeatable trip currents, such that there is little or no drift or shift after multiple events. Finally, TBUs are preferably resettable or recover automatically after a surge is experienced. Other details about TBUs are described in U.S. Pat. No. 5,742,463, by Richard A. Harris, dated Apr. 21, 1998, as well as PCT/AU03/00175 and PCT/AU03/00848, all of which are hereby incorporated by reference.

Currently, some protection devices, such as fuses and thyristors, are unable to control, monitor, or collect and transfer data related to the load or condition of the line in which they are placed. Such monitoring and data collection/transmission can be desirable in a variety of circumstances as described below.

Intelligent Transient Blocking Unit

The present inventions are directed toward a TBU system that includes a TBU combined with one or more “intelligent” features, such as on/off, control and/or monitoring features, including preferably the capability to collect and transfer such data. These functions (singly or in combination) are referred to herein as intelligent features, or overhead functionality for the TBU.

For example, in one embodiment, TBU elements are adapted with a status indication switch or indicator. In another embodiment, TBU elements are adapted with event logging for over voltage conditions, over current conditions, preferably including an indication of when the event occurred and an amount of energy that was let through. In another embodiment, TBU elements are adapted with circuitry for line status indicators that monitor both input and output signals, input and output voltage and current monitoring, and signal health monitoring. In yet another embodiment, TBU elements are combined with an on/off switch with which to control the TBU, a programmable TBU trigger current and voltage, and an I²C interface to interrogate and control the TBU. In yet further embodiments, one or more of the above mentioned functions are implemented in combination with the TBU circuitry.

Thus, the example embodiments of the present innovations variously describe one or more of the combination of intelligent functions, which include control of the TBU, including on/off control, reset control, trigger current control, and varying the magnitude of the trigger current; alarms for various events; event measurement and logging; and line monitoring, such as input and output monitoring. In addition, the present innovations preferably include means for transmitting information related to the above described intelligent functions, for example, to a computer system for monitoring such events.

These and other innovative embodiments are described more fully below.

### BRIEF DESCRIPTION OF THE DRAWINGS

The disclosed inventions will be described with reference to the accompanying drawings, which show important sample embodiments of the invention and which are incorporated in the specification hereof by reference, wherein:

FIG. 1 shows an example protection circuit consistent with implementing a preferred embodiment of the present innovations.

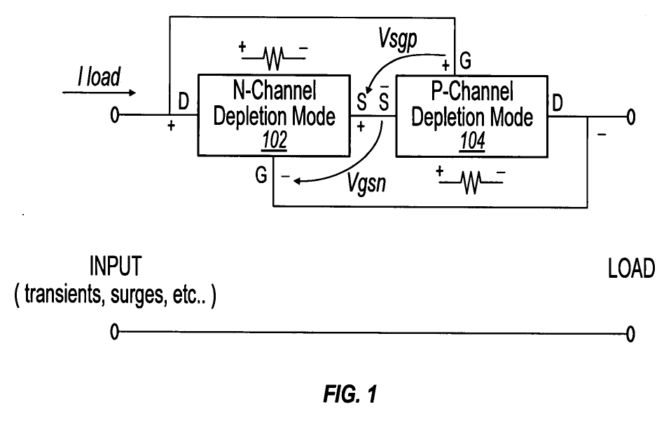

FIG. 2 shows a bi-directional TBU consistent with implementing a preferred embodiment of the present innovations.

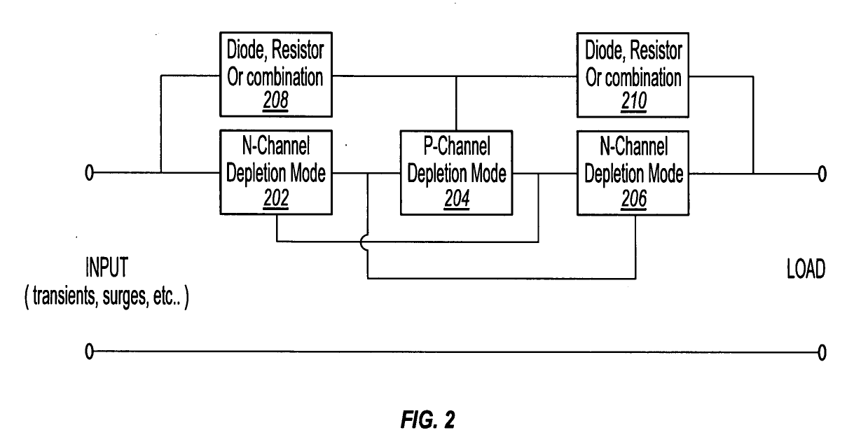

FIG. 3 shows a bi-directional TBU consistent with implementing a preferred embodiment of the present innovations.

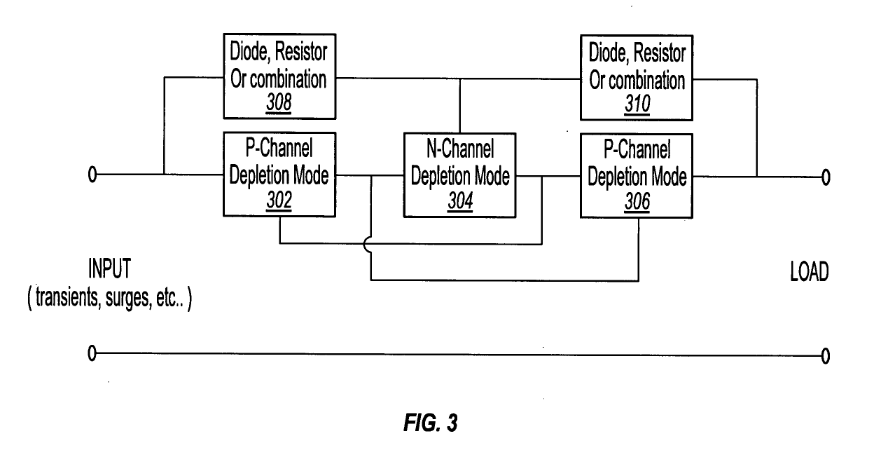

FIG. 4 shows an example TBU with status indicator consistent with implementing a preferred embodiment of the present innovations.

FIG. 5 shows an example TBU with dual status indicators consistent with implementing a preferred embodiment of the present innovations.

FIG. 6 shows a side view of a layout for a sense FET consistent with a preferred embodiment of the present innovations.

FIG. 7 shows a side view of a layout for a sense FET consistent with a preferred embodiment of the present innovations.

FIG. 8 shows both thin and thick gate sense FETs consistent with a preferred embodiment of the present innovations.

FIG. 9 shows a TBU with on/off control consistent with a preferred embodiment of the present innovations.

FIG. 10 shows a TBU with on/off control consistent with a preferred embodiment of the present innovations.

FIG. 11 shows a TBU with on/off control consistent with a preferred embodiment of the present innovations.

FIGS. 12A and 12B show a TBU with on/off control consistent with a preferred embodiment of the present innovations.

FIG. 13A and 13B show a TBU with on/off control consistent with a preferred embodiment of the present innovations.

FIG. 14 shows a TBU with on/off control using opto-coupled signal consistent with a preferred embodiment of the present innovations.

FIG. 15 shows a TBU with on/off control using opto-coupled signal consistent with a preferred embodiment of the present innovations.

FIG. 16 shows a TBU with programmable trigger current consistent with a preferred embodiment of the present innovations.

FIG. 17 shows one example of programmable resistors consistent with a preferred embodiment of the present innovations.

FIG. 19 shows a signal monitoring TBU consistent with a preferred embodiment of the present innovations.

FIG. 19 shows a signal monitoring TBU consistent with a preferred embodiment of the present innovations.

FIG. 20 shows a signal monitoring TBU consistent with a preferred embodiment of the present innovations.

FIG. 21 shows process options for interdigitated PJFETs consistent with a preferred embodiment of the present innovations.

### DETAILED DESCRIPTION OF THE PREFERRED EMBODIMENTS

The numerous innovative teachings of the present application will be described with particular reference to the presently preferred embodiment (by way of example, and not of limitation).

In one example embodiment, a TBU is combined with circuits and devices for adding one or more of a plurality of features, as described further below. Though a specific TBU is used in examples to describe the innovative concepts herein disclosed, the scope of the present innovations is consistent with implementations using examples other than the specific circuits shown, which are only intended to be illustrative and not limiting.

In a preferred embodiment, the innovative features described herein are implemented in a single intelligent “core” protection circuit, fabricated on a single semiconductor die. However, other embodiments are within the scope of the present innovations, including implementing features that are separately fabricated, and packaged with or separately from the basic TBU circuitry. Discrete devices can also be used to implement embodiments of the present innovations.

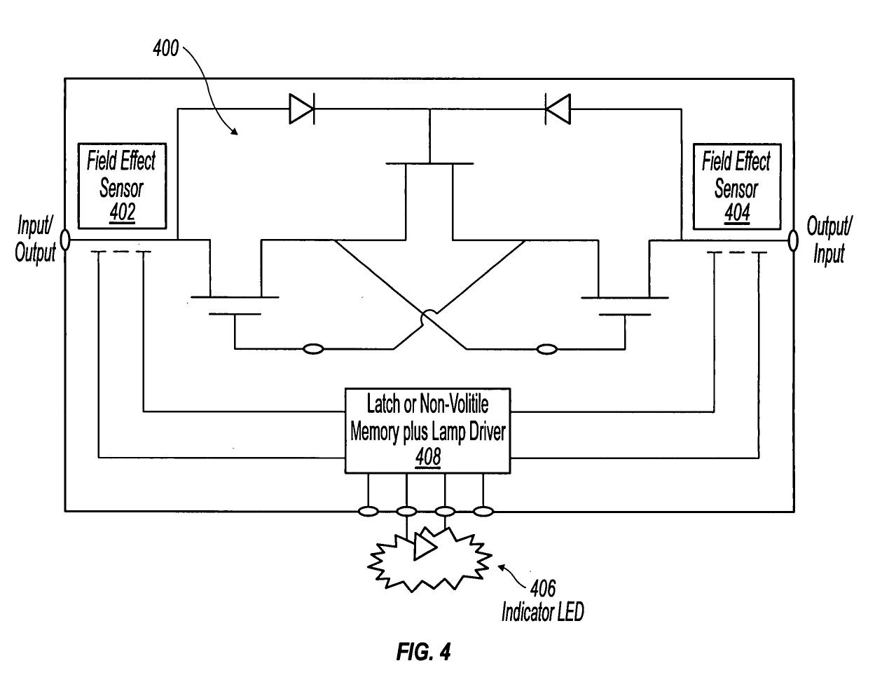

FIG. 4 shows one such preferred embodiment of the present innovations. This example implementation includes a bi-directional TBU unit 400 combined with a first field effect sense transistor 402 on the input and a second 404 on the output of the TBU unit. (In this context, a “sense transistor” refers to a transistor that detects transients, such as a multi-terminal device which is controlled by a gate which is capacitively coupled to a transient.) In a preferred embodiment, there is no DC (direct connection) coupling. The FET sensor threshold voltage is preferably adjusted to match the over-voltage protection level, so that if the over-voltage function is tripped due, for example, to a surge, the FET sensors will cause the indicator 406 to operate. Threshold voltage can be adjusted according to a variety of methods, including but not limited to variation of oxide thickness, substrate doping, substrate-surface orientation, and materials used.

In this example, a single indicator 406 is shown, functioning with a latch or non-volatile memory plus lamp driver 408. In preferred embodiments, these elements are used to record any transient, such as duration and intensity and time of occurrence. This information can be later transferred and/or read by an operator to gather information about events that occurred in the circuit.

In the example implementation of the system of FIG. 4, the combined TBU and status indicator are subjected to a surge which, after triggering the TBU, activates the sense FET once its sense threshold is exceeded. Because the FET sensor's threshold voltage is adjusted to match the over-voltage function, the latch is activated, which turns on the indicator lamp or LED. This indicator is in turn noticed by another sensor or by a human operator to indicate the status of the TBU, in this case, that the over-voltage function has been activated.

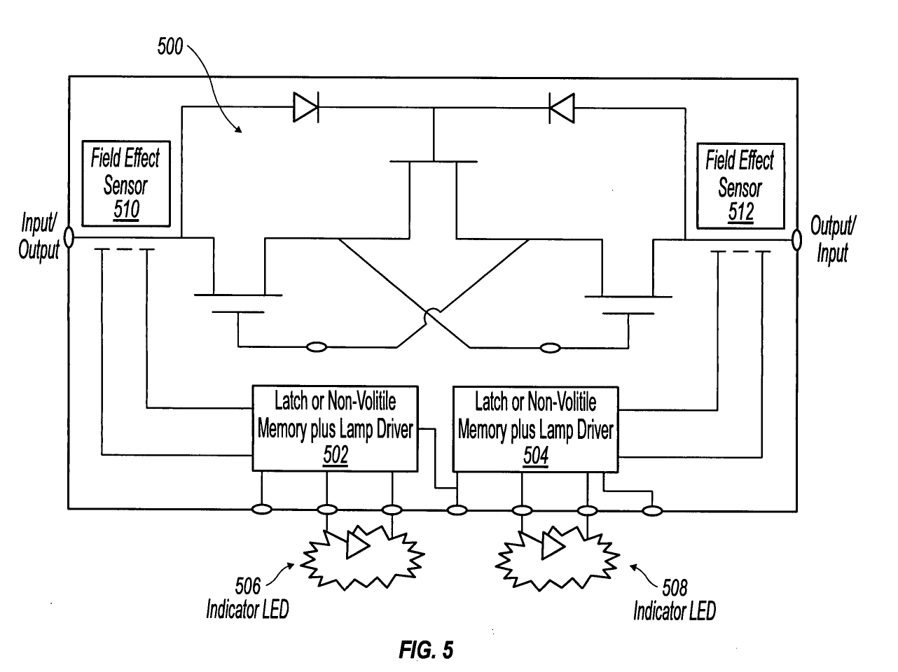

FIG. 5 depicts another example embodiment of the combined status indicator and TBU system. In this example, dual LED driver and latch or non-volatile memory units 502, 504 are combined with the TBU 500, each connected to independent LED indicators 506, 508 and to sensors 510, 512. The embodiment of FIG. 5 can be implemented in such a way as to indicate whether the over-voltage-function of the TBU was tripped at the input or the output of the TBU unit.

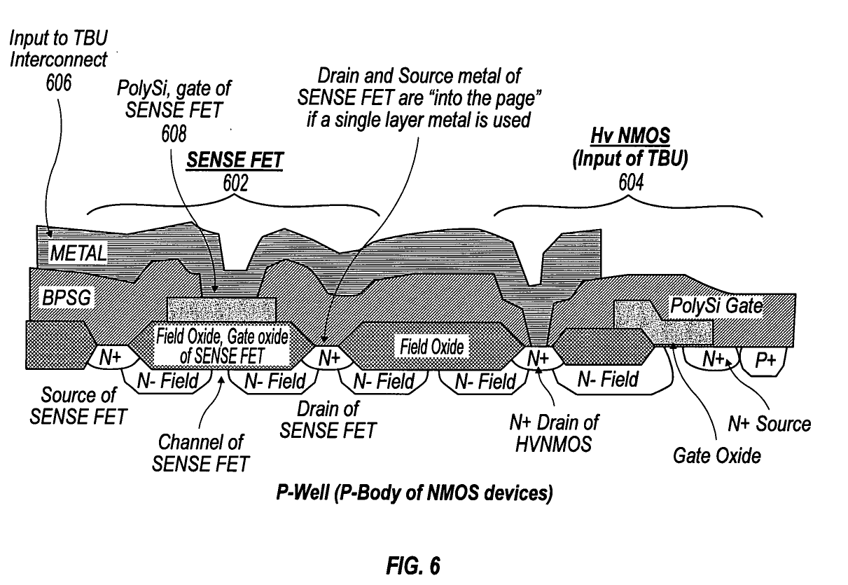

An example of a sense FET layout is described with reference to FIG. 6. In this example, a partial diagram of an integrated circuit embodying one example of the present innovations is shown. A sense FET 602 is shown next to the high voltage NMOS device 604, which serves in this example as the input device for the TBU (not shown in this figure). Metal interconnect 606 connects the gate 608 of the sense FET with the TBU interconnect as input to the TBU interconnect.

Some options for this example configuration include a gate of the sense FET made as polysilicon over the field oxide (as shown in FIG. 6), or, alternately, metal interconnect and inter level dielectric, such as BPSG (boro-phospho-silicate glass) over the field oxide. The threshold voltage of the sense FET can be adjusted, for example, by adding doping in the P-well channel region, or by adjusting the gate oxide thickness. In this side view, the drain and source metal of the sense FET are into the page if a single metal layer is used.

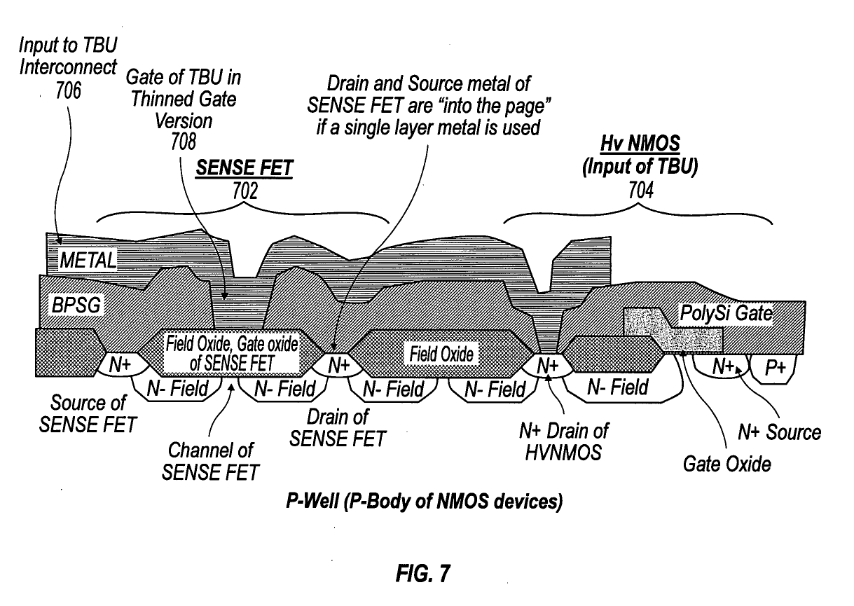

FIG. 7 shows another example implementation of a preferred embodiment of the present innovations. In this example, a partial diagram of an integrated circuit is shown. A sense FET 702 is shown next to a high voltage NMOS device 705, which serves in this example as the input device for the TBU. This version of the present innovations depicts the gate oxide 708 of the sense FET directly connected to the metal interconnect 706 input to the TBU. As in FIG. 6, the drain and source metal of the sense FET are into the page if a single layer metal is used.

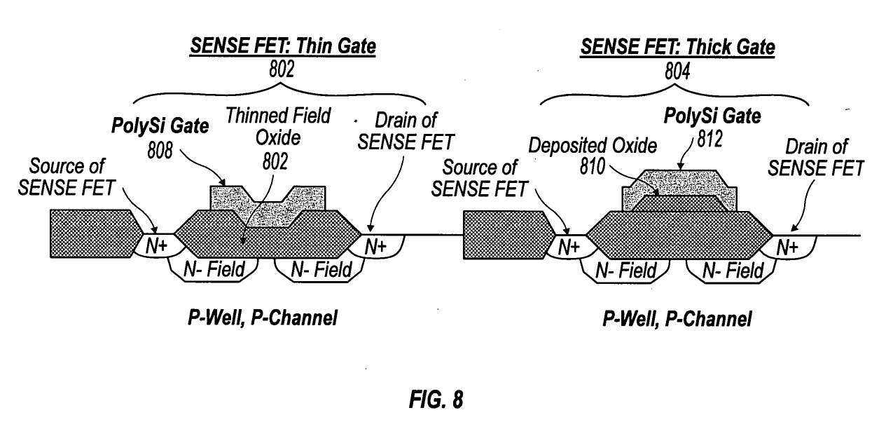

FIG. 8 shows a more detailed view of the gates of two example sense FETs the first 802 with a thin gate layout, the second 804 with a thick gate. On the left side, a thin gate example 802 is depicted. In this example implementation the field oxide 806 has been thinned to create an overall thinner gate 808. The thinned field oxide 806 is shown with a polysilicon gate 808 over the field oxide. This is done, in one embodiment, using a dedicated mask or wet or dry etch, prior to depositing the gate polysilicon.

On the right side of FIG. 8, a thick gate example 804 is shown. Thicker gate oxide 810 is preferably obtained by depositing the oxide, removing it from the wafer except in the sense FET channel region, and densifying it prior to depositing the gate polysilicon 812. The sense FET threshold can be adjusted by using implants in the oxide or the channel.

The examples of FIG. 8 show the polysilicon gate versions, but the metal gate versions are also of course possible, as depicted, for example, in FIG. 7.

For some applications, it can be desirable to activate the TBU even if there is no surge or transient. For example, prior to disconnecting a line from a system, it ay be desirable to place it in a high impedance state by using the TBU.

In the following examples, the term “ON” is defined as a conductive state, while “OFF” is defined as an open-circuit, or non-conductive state.

The present innovations include several embodiments for turning the TBU off or on. Means of turning the TBU on independently of the bias conditions is generally not allowed since this could result in damage to the TBU or the load. However, if required, the TBU could be forced on by altering the gate connection of the FETs, for example, by shorting the gate to the source.

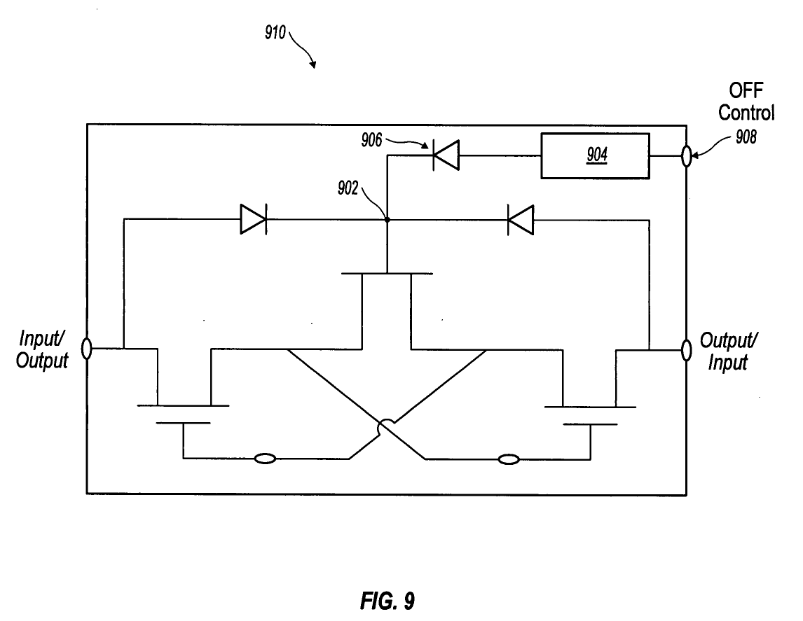

FIG. 9 shows one example embodiment consistent with triggering the TBU from a conductive state to an open-circuit state. In this example, an NMOS depletion mode device turns off as the voltage drop across the PJFET increases with increasing current. Applying an external bias to the PJFET can trigger the TBU on demand. This requires a bias equivalent to the pinch-off voltage of the PJFET, which can be quite high (e.g., 5 to 15 volts range is common).

In FIG. 9, node 902 is connected to an NMOS depletion mode device 904 through diode 906. The NMOs depletion mode device 904 is also connected to an off control 908. This example shows a bidirectional TBU 910 implementation.

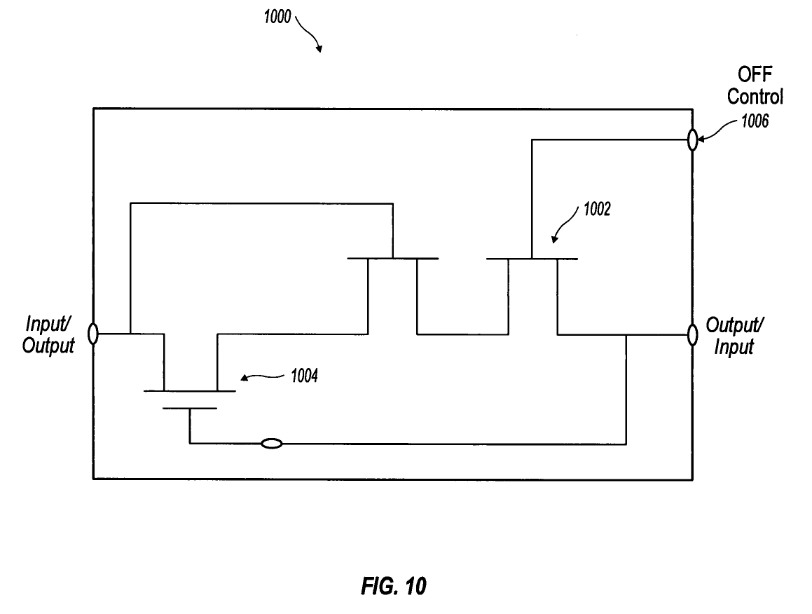

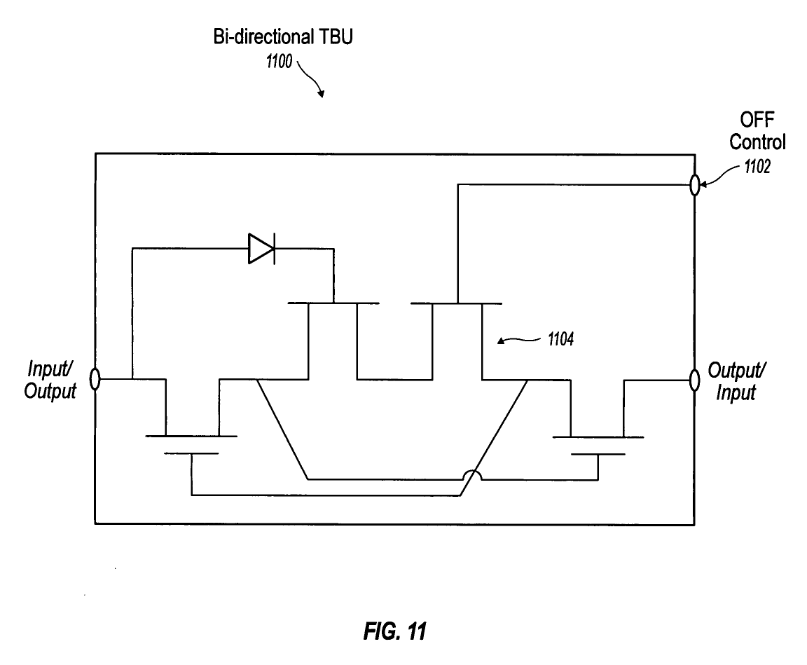

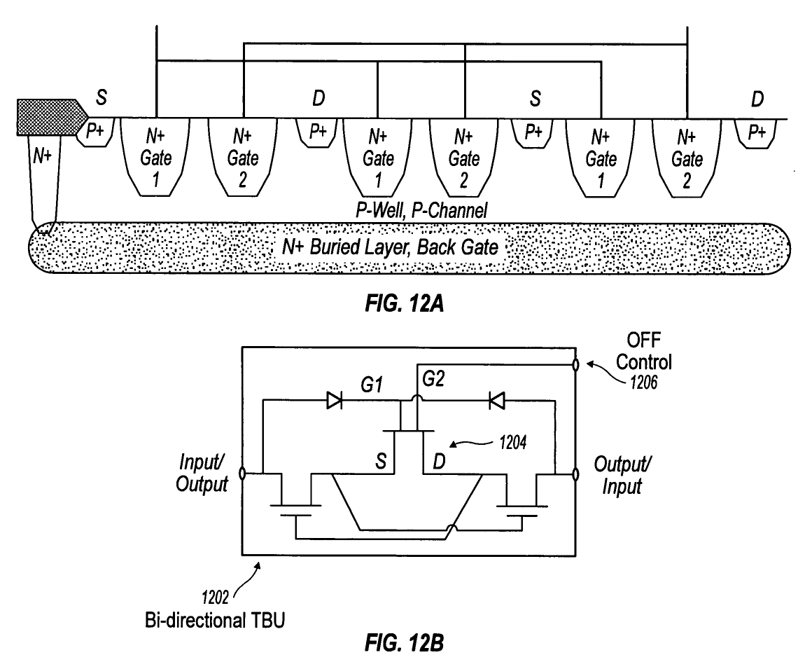

FIG. 10 shows a unidirectional TBU 1000 implementation. In this example embodiment, the NMOS device 1004 is turned off by controlling its gate to source bias (V_{gs}). This can be achieved by inserting a low voltage, low-resistance normally “on” depletion mode device (preferably an FET, such as a MOSFET or JFET, for example) in series with the drain/source interconnect of the PJFET device (see FIGS. 10, and 11, below). Alternately, the device can be turned off by using a double gate PJFET structure (see FIG. 12, below). FIG. 10 depicts one embodiment of the present innovations, inserting a FET 1002 (in this example, a PJFET) in series to control the V_{gs} bias of the NMOS 1004. Added FET 1002 is situated between the gate of the N-channel depletion mode device 1004 and an off control 1006. A positive gate bias applied to the OFF control pin 1006 will pinch off the p-channel FET device 1002, which effectively raises the resistance, and increases the V_{gs} applied to the gate of the NMOS device 1004. Thus, by controlling the gate bias of device 1002 through control 1006, the TBU can be effectively turned on or off.

Another example embodiment includes a data transfer port, for example, implemented with pin 1006, which sends a signal outside the TBU. In some embodiments, this signal is used to collect data relating to the status and function of the TBU and to transfer that data to other processing circuitry for collection and monitoring. Other pins can be added to the system shown in FIG. 10, in order to implement such data collection and transfer, for example, by monitoring the status of a line and signaling its status at predetermined times or when events occur. This allows the history of the TBU to be reported and collected for further use or study. Collection and/or transfer of the events of the TBU system can be implemented with various ones of the embodiments described herein. For example, in one embodiment, information gathered about the TBU and events or status of the TBU can be stored on-chip in an analog or digital format, and can be sent off chip or read using one or more pins dedicated to that purpose. Alternately, these innovations can be implemented using circuitry which enables already-existing pins to be used for multiple purposes, including the off-chip transfer of collected information.

In another example embodiment, FIG. 11 shows a bi-directional TBU 1100 with off control 1102 implementing FET 1104. In this example, the bias applied to the off control device 1104 may be used to determine which direction is turned off in the bi-directional TBU. For example, for a bi-directional TBU, it is possible to control from which direction the TBU is “turned off,” or in which direction the TBU effectively prevents surges or electrical communication. Thus, the present innovations include direction-preferential on/off control of the TBU. Such a system can be implemented, for example, in an AC environment by knowing the timing of the AC signal, so that the TBU can toggle in synchronization to the signal to effectively cancel half the AC signal, or the part corresponding with electrical transmission in a given direction. This would stop the signal from transmitting in one direction while allowing it to transmit in the other.

It is noted that, for example in the embodiments shown in FIGS. 10 and 11, element 1104 (described as FET, above) can instead be implemented as controlled variable resistor. In this embodiment, the innovative system can be used to control not only the on or off state of the TBU, but it can also be used to control the current of the TBU, according to the state of the variable resistor 1104.

FIGS. 12A and 12B show the split gate PJFET implementation of an on/off control for a TBU. In this example implementation, FIG. 12A shows the processing structure of the device, while FIG. 12B shows a circuit diagram corresponding to FIG. 12A. FIG. 12B shows the TBU 1202 with split gate JFET device 1204 having gate 1 (G1) and gate 2 (G2). In this example, gate 2 connects to the off control pin 1206.

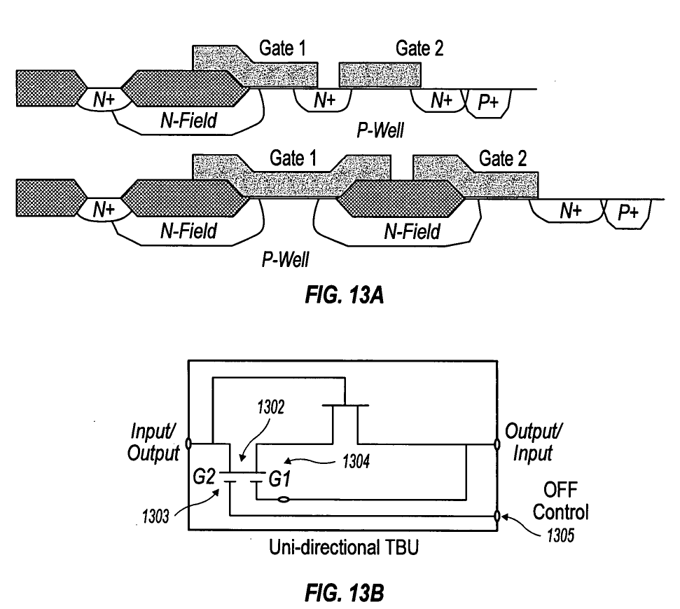

In yet another embodiment of the off control for a TBU, FIGS. 13A and 13B show, respectively, side views of two split gate NMOS versions (FIG. 13A) and a circuit diagram of a split gate NMOS version (FIG. 13B). FIG. 13B shows an implementation wherein on/off control is achieved by direct control of the HV NMOS gate 1302. Gate 1302 includes two parts, 1303, 1304. A negative bias applied to the off control gate 1303, which is connected to the off control 1305, turns the TBU off. A bi-directional version with twin control, for independent control of the direction turned off, is also possible.

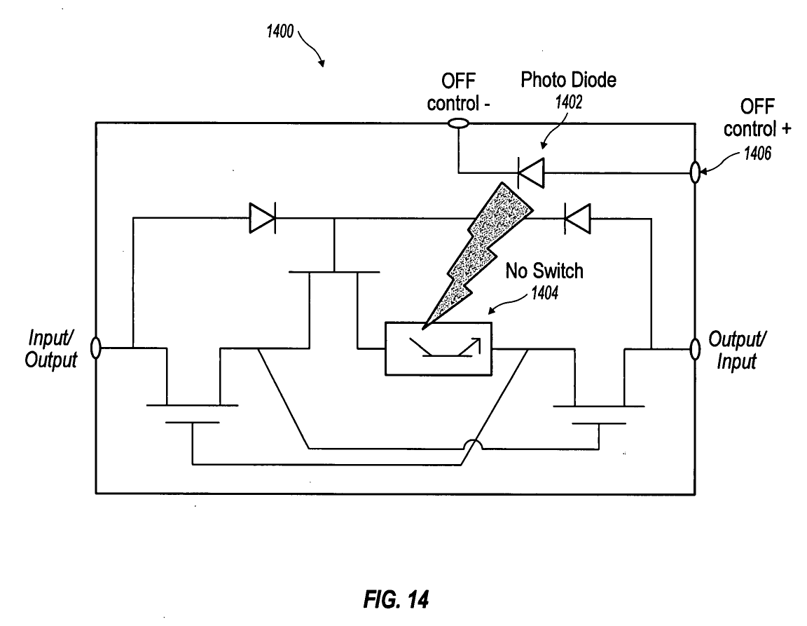

FIG. 14 shows a similar arrangement for providing off control to a TBU circuit. In this example implementation, an opto-coupled switch 1404 replaces the PJFET series device shown in earlier embodiments. The switch 1404 is sensitive to emissions from photo diode 1402 which is connected to off control 1406 When off control 1406 is activated, photo diode 1402 sends an optical signal to switch 1404, which in turn turns the TBU 1400 off. The switch 1404 is normally on (NO), and has higher resistance when photo diode 1402 is turned on. This turns the NMOS of by increasing negative Vgs.

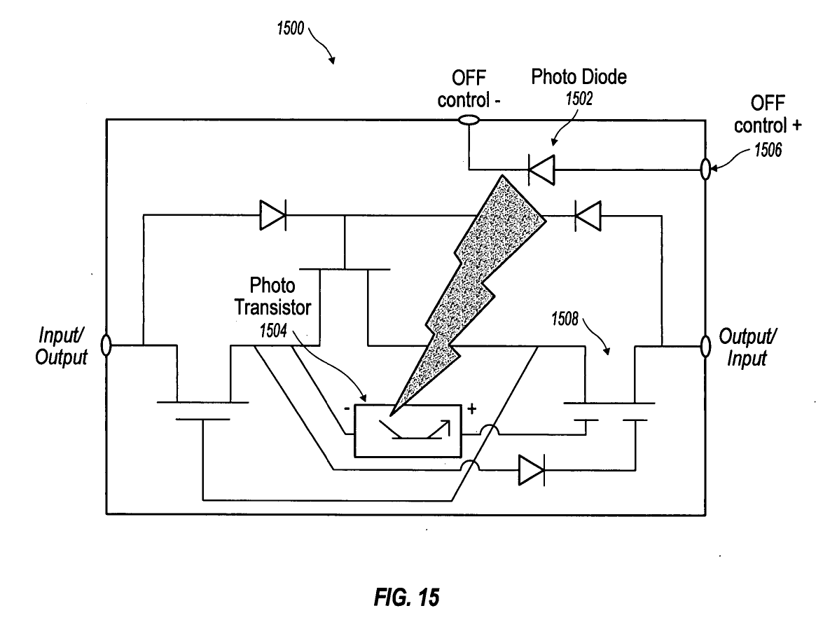

FIG. 15 shows another implementation using an opto-coupled switch 1504. In this example, switch 1504 is sensitive to emissions from photo diode 1502 which itself is connected to off control 1506. The switch 1504 comprises, preferably, a photo transistor that is connected, in this example, one control gate of a split gate device 1508, as discussed above. This provides isolated control fo the TBU 1500. In this example, the double gate is realized by using a lateral HV NMOS. A symmetric version using two split gate NMOS devices is also possible for symmetric behavior.

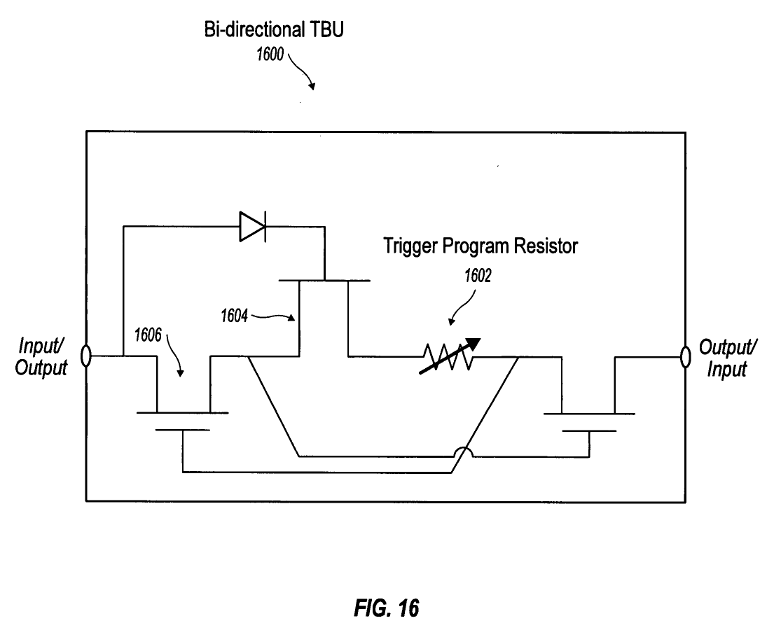

The current innovations include a trigger current of the TBU which can be programmed. In FIG. 16, a bi-directional TBU 1600 is depicted with a trigger program resistor 1602 which is situated to control the V_{gs} of NMOS device 1606. The resistor 1602 is preferably placed in series with the PJFET device 1604 to increase its resistance. With this approach, the highest trigger current is when the additional program resistor 1602 has a zero value. As the resistance of resistor 1602 goes up, the trip current of the device is reduced, increasing sensitivity of the TBU. Thus, by managing the resistance of resistor 1602, the trip current of the TBU can be adjusted or controlled.

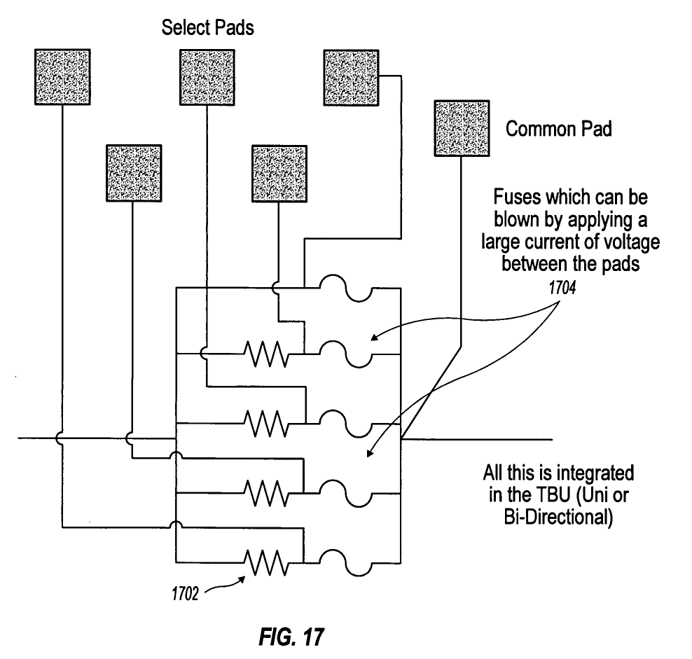

FIG. 17 shows one possible implementation of a programmable trigger current consistent with embodiments of the present innovations. In this example, the required resistors 1702 are included in the layout along with fuses or fuse links 1704 that can be blown to select the appropriate combination of resistors. These are connected during processing at the metal mask, or interconnect level. The layout is preferably combined in the TBU, whether a uni- or bi-directional implementation. This implementation provides a set of discrete current levels.

The present innovations include capability for signal monitoring. Monitoring the input and/or output signals of the TBU may be required or useful in some applications. For example, the peak voltage and current during a transient or surge may be determined or needed. Monitoring the voltage and current levels of the input and output lines under normal operating conditions may also be desirable. Voltage sensing can be done in preferred embodiments using a resistor divider network, as described below. Likewise, current sensing can be done by measuring the voltage drop across one of the FETs, and using a smaller scaled down device to determine the current. In preferred embodiments, the techniques used to sense the high voltage and current levels is isolated.

FIG. 18 shows one example implementation that offers signal monitoring in the form of voltage sensing. In this example, the resistors R1, R2, and R3 provide a resistor divider network, wherein R1=R3>>R2. R1 and R3 are large in order to provide isolation, and to draw low current from the input and output. Polarity of the voltage across R2 gives the direction of the voltage transient through the TBU, as read by an operational amplifier 1802. Op amp 1802 outputs an analog signal. This embodiment can have other variations, such as a peak detector circuit being added. Also, resistors can be used on chip or off chip (in a package). They can be polysilicon, diffused, or thin film resistors, for example.

In preferred embodiments, the surge protection system includes capability to collect and transfer data outside the surge protection system.

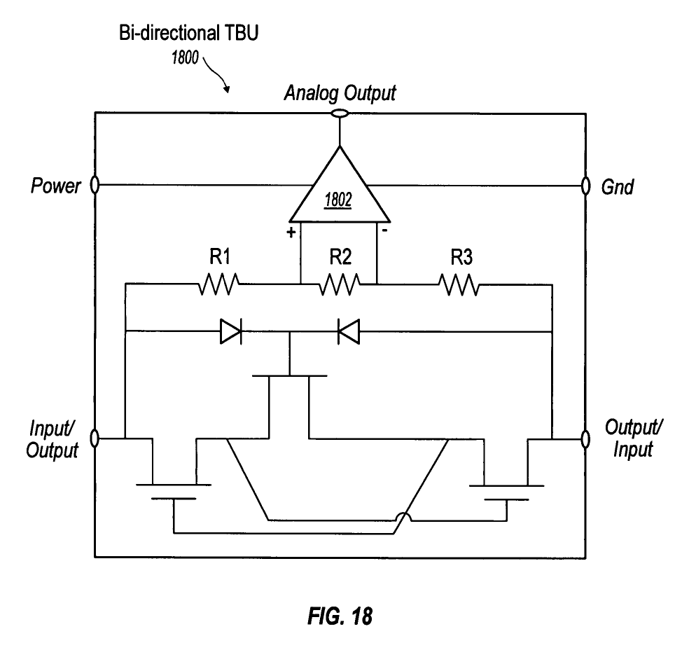

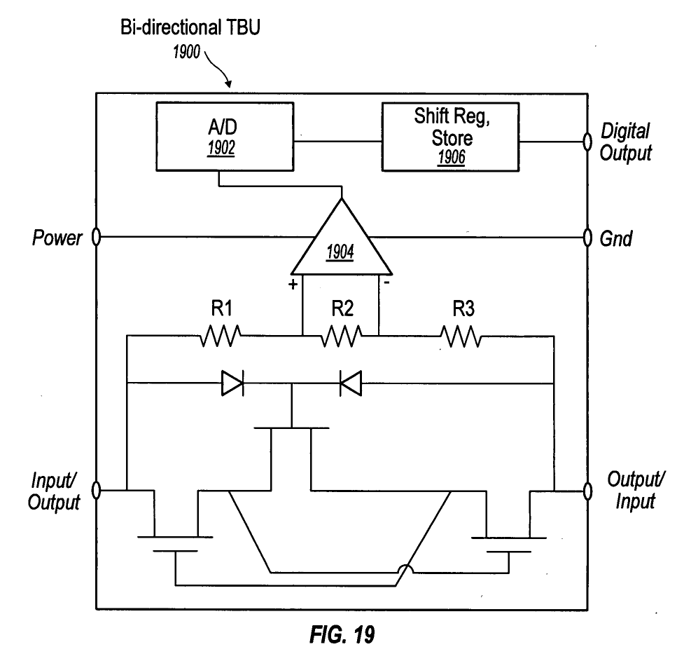

FIG. 19 shows another implementation for signal monitoring, specifically voltage sensing. In this example, digital output is provided by an on- or off-chip analog/digital converter 1902 which received output from op-amp 2004. In this example implementation, data is stored on-chip using non-volatile memory, such as shift register 1906.

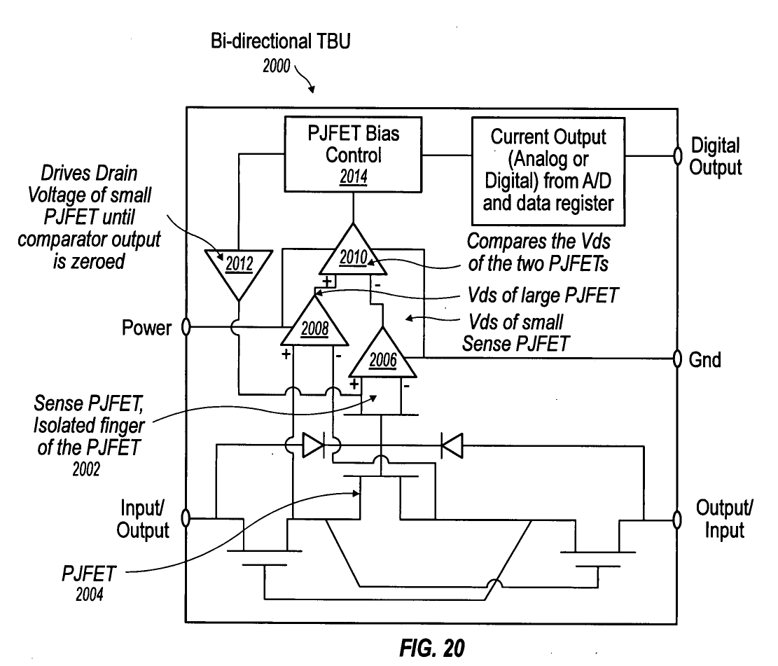

FIG. 20 shows one example of a system wherein current sensing and signal monitoring is implemented. In this example, a sense PJFET 2002 is combined with a normal PJFET 2004, in an “interdigitated” configuration. The smaller PJFET is a portion of the existing PJFET, such as one finger being shared between the two. A polarity detector (in the form of several op-amps) is also shown. Using input from op-amps 2006, 2008, which are governed by sense PJFET 2002 and JPFET 2004 respectively, op-amp 2010 compares the Vds of the two PJFETs. This output is fed into PJFET bias control 2014 which outputs a result, and which participates in a feedback loop implemented with op-amp 2012, which drives the drain voltage of the sense PJFET 2002 until the comparator output is zeroed.

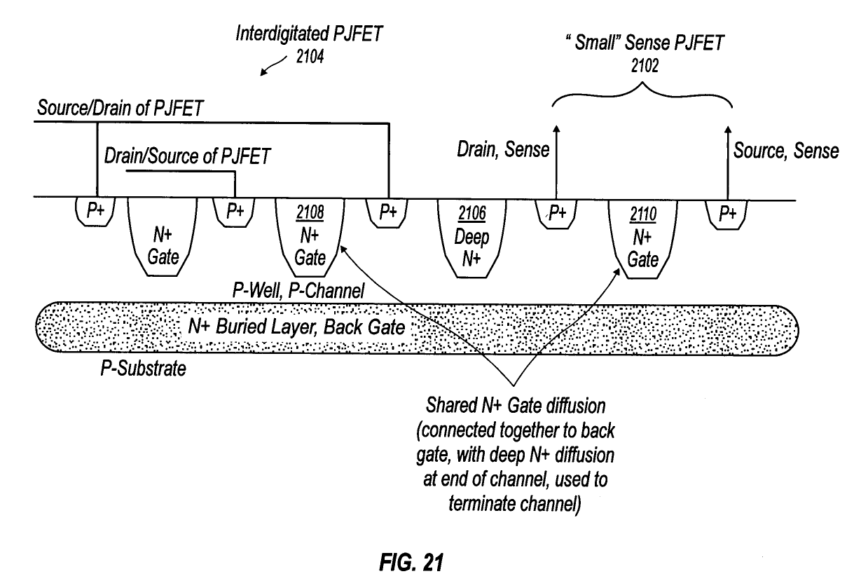

FIG. 21 shows one example of the combined PJFETs depicted in FIG. 20. In this example, PJFET 2104 and sense PJFET 2102 are combined, sharing N+ gate diffusion 2108, 2110, connected together to a back gate, with deep N+ diffusion 2106 at the end of each channel used to terminate the channel.

In one embodiment, the present innovations comprise a surge protection system, comprising: a protection circuit having a plurality of devices which provide over-current and/or over-voltage protection; and a plurality of circuit elements operably connected with the protection circuit which provides on/off control.

In another embodiment, the present innovations comprise a surge protection system, comprising: a protection circuit having a plurality of devices which provide over-current and/or over-voltage protection; and a plurality of circuit elements operably connected to the protection circuit which provide status indication.

In another embodiment, the present innovations comprise a surge protection system, comprising: a protection circuit having a plurality of devices which provide over-current and/or over-voltage protection; and a plurality of circuit elements operably connected with the protection circuit which provide at lest one function from the group consisting of: on/off control, status indication, event logging, and monitoring.

In another embodiment, the present innovations comprise a surge protection system, comprising: a transient blocking unit (TBU); and additional circuitry operably connected to the TBU which provides overhead functionality for said TBU.

In another embodiment, the present innovations comprise a surge protection system, comprising: a transient blocking unit (TBU) and; a sense transistor operably connected to the TBU and adjusted to match an over-voltage protection level of the TBU so that when the over-voltage protection of the TBU is triggered, the sense transistor triggers an indicator.

In another embodiment, the present innovations comprise a surge protection system, comprising: a transient blocking unit (TBU) comprising a p-channel device and an n-channel device operably connected to provide over-voltage and/or over-current protection; and a control device operably connected between the drain of the p-channel device and the gate of the n-channel device, the gate of the control device being operably connected to an exterior pin.

In another embodiment, the present innovations comprise a surge protection system, comprising: a transient blocking unit (TBU) comprising a plurality of series connected depletion mode n-channel and p-channel transistors operably connected to an operational amplifier, wherein the operational amplifier outputs an analog signal associated with events or status of the TBU.

In another embodiment, the present innovations comprise an over-voltage and over-current protection circuit for blocking transient surges from sensitive loads, comprising: a first plurality of devices to perform a current limiting function; a second plurality of devices to perform an over-voltage protection function; a third plurality of devices to perform intelligent functions; wherein the first plurality and second plurality of devices are n-channel and p-channel depletion mode devices connected in series; and wherein the intelligent functions include one or more features selected from the group consisting of: on/off control, reset control, trigger current control, alarm, event monitoring, event logging, line monitoring, and input/output monitoring.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

Modifications and Variations

As will be recognized by those skilled in the art, the innovative concepts described in the present application can be modified and varied over a tremendous range of applications, and accordingly the scope of patented subject matter is not limited by any of the specific exemplary teachings given.

The TBU depicted in the examples can of course be modified within the scope of the present innovative concepts. N and P structures can be swapped, correspondingly.

The TBU can be part of an integrated circuit, or be comprised of discrete devices. The added “intelligent” functionality described herein can also be integrated or discrete with respect to the TBU. Various manufacturing techniques can be used to create the devices, all within the scope of the present innovations.

The example devices described herein are only not intended to limit the types of devices that can be used for implementing the innovations described herein.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle. Moreover, the claims filed with this application are intended to be as comprehensive as possible: EVERY novel and nonobvious disclosed invention is intended to be covered, and NO subject matter is being intentionally abandoned, disclaimed, or dedicated.

What is claimed is:

1. A surge protection system, comprising:
a protection circuit having a plurality of devices which provide over-current and/or over-voltage protection; and
a plurality of circuit elements operably connected with the protection circuit which provides on/off control.

2. The system of claim 1, wherein the plurality of circuit elements which provide on/off control comprise a field effect device that controls gate to source bias of a device of the protection circuit.

3. The system of claim 1, wherein a device of the protection circuit includes a split gate, wherein at least one contact of the split gate is operably connected to an off control pin.

4. The system of claim 3, wherein the split gate device is selected from the group consisting of: a p-channel depletion mode device and an n-channel depletion mode device.

5. The system of claim 1, wherein the plurality of circuit elements comprises an opto-coupled switch and a photo diode, wherein the opto-coupled switch is sensitive to signals of the photo diode.

6. The system of claim 5, wherein the photo-diode is operably connected to an on/off control pin.

7. The system of claim 5, wherein when the photo-diode is turned on, the gate-source voltage of an NMOS device of the core is increased.

8. The system of claim 1, further comprising an output port which sends a signal outside the surge protection system, the signal carrying information related to events occurring at the surge protection system.

9. A surge protection system, comprising:
a protection circuit having a plurality of devices which provide over-current and/or over-voltage protection; and
a plurality of circuit elements operably connected to the protection circuit which provide status indication.

10. The system of claim 9, wherein the plurality of circuit elements comprises a trigger program resistor operably connected to control the gate source voltage of a device of the protection circuit, wherein the trigger program resistor determines the current at which the protection circuit is triggered from a conductive state to a substantially non-conductive state.

11. The system of claim 10, wherein the trigger resistor is a variable resistor operably connected to control the gate source voltage of an NMOS device of the protection circuit, and wherein the trigger resistor is placed in series with a PJFET device of the protection circuit to increase resistance.

12. The system of claim 9, wherein a field effect transistor is operably connected to the protection circuit, and wherein the gate of the field effect transistor is operably connected to a trigger current set pin.

13. The system of claim 9, further comprising an output port which sends a signal outside the surge protection system, the signal carrying information related to events occurring at the surge protection system.

14. A surge protection system, comprising:
a protection circuit having a plurality of devices which provide over-current and/or over-voltage protection; and
a plurality of circuit elements operably connected with the protection circuit which provide at lest one function from the group consisting of: on/off control, status indication, event logging, and monitoring.

15. The system of claim 14, wherein the plurality of circuit elements are combined with the protection circuit in a single package.

16. The system of claim 14, further comprising an output port which sends a signal outside the surge protection system, the signal carrying information related to events occurring at the surge protection system.

17. The system of claim 14, wherein the plurality of circuit elements are combined with the protection circuit in a single integrated circuit.

18. A surge protection system, comprising:
a transient blocking unit (TBU); and
additional circuitry operably connected to the TBU which provides overhead functionality for said TBU.

19. The system of claim 18, wherein the TBU and the additional circuitry are implemented in a single package.

20. The system of claim 18, wherein said overhead functionality includes monitoring the quality of a line to which the TBU is connected.

21. The system of claim 18, wherein the TBU and the additional circuitry are implemented in a single integrated circuit.

22. The system of claim 18, wherein said overhead functionality provides at least one of the group consisting of: on/off control, status indication, event logging, and monitoring.

23. The system of claim 18, further comprising an output port which sends a signal outside the surge protection system, the signal carrying information related to events occurring at the surge protection system.

24. A surge protection system, comprising:
a transient blocking unit (TBU); and
data collection circuitry in a common package with said TBU which collects and reports the history of operation of said TBU.

25. The system of claim 24, wherein the TBU and the data collection circuitry are implemented in a single integrated circuit.

26. The system of claim 24, wherein the history of operation of the TBU is reported to collection circuitry outside the surge protection system.

27. The system of claim 24, further comprising an output port operably connected to the data collection circuitry which sends a signal outside the surge protection system, the signal carrying information related to events occurring at the surge protection system.

28. A surge protection system, comprising:
a transient blocking unit (TBU) and;
a sense transistor operably connected to the TBU and adjusted to match an over-voltage protection level of the TBU so that when the over-voltage protection of the TBU is triggered, the sense transistor triggers an indicator.

29. The system of claim 28, further comprising a latch operably connected to the sense transistor.

30. The system of claim 29, wherein the indicator is an LED.

31. The system of claim 28, wherein the sense transistor includes a gate region comprising polysilicon over an oxide, the polysilicon being operably connected to a metal interconnect.

32. The system of claim 31, wherein the oxide is thinned prior to depositing the polysilicon.

33. The system of claim 31, wherein the odixe is thickened by depositing more oxide prior to depositing the polysilicon.

34. A surge protection system, comprising:
a transient blocking unit (TBU) comprising a p-channel device and an n-channel device operably connected to provide over-voltage and/or over-current protection; and
a control device operably connected between the drain of the p-channel device and the gate of the n-channel device, the gate of the control device being operably connected to an exterior pin.

35. The system of claim 34, wherein the exterior pin is an on/off control pin.

36. The system of claim 34, wherein the TBU is bi-directional and includes a second n-channel device.

37. A surge protection system, comprising:
a transient blocking unit (TBU) comprising a plurality of series connected depletion mode n-channel and p-channel transistors operably connected to an operational amplifier, wherein the operational amplifier outputs an analog signal associated with events or status of the TBU.

38. An over-voltage and over-current protection circuit for blocking transient surges from sensitive loads, comprising:
a first plurality of devices to perform a current limiting function;
a second plurality of devices to perform an over-voltage protection function;
a third plurality of devices to perform intelligent functions;
wherein the first plurality and second plurality of devices are n-channel and p-channel depletion mode devices connected in series; and
wherein the intelligent functions include one or more features selected from the group consisting of: on/off control, reset control, trigger current control, alarm, event monitoring, event logging, line monitoring, and input/output monitoring.
